(19) United States
(12) Patent Application Publication
(10) Pub. No.: US 2011/0123932 A1
(43) Pub. Date: May 26, 2011

(54) METHOD FOR FORMING A FLUID EJECTION DEVICE

(76) Inventors: Yimin Guan, Lexington, KY (US); Burton Lee Joyner, II, Lexington, KY (US); Zachary Justin Reitmeier, Lexington, KY (US)

(21) Appl. No.: 12/622,479

(22) Filed: Nov. 20, 2009

(51) Int. Cl. G03F 7/20; H01L 21/3065; C23F 1/00; H01L 21/308

(52) U.S. Cl. 430/320; 438/21; 216/27; 257/E21.218; 257/E21.231

(57) ABSTRACT

Methods are described for forming a fluid ejection device on a substrate having a first surface and a second surface, the first surface having plurality of electrical heater elements. A sacrificial polymer layer is added over the first surface, a conformal material over the sacrificial polymer layer forms a nozzle layer, the sacrificial polymer is then removed to form ink ejection chambers, the nozzle layer is removed to form nozzle holes, a mask layer is used to form an exposed region and an unexposed region, the exposed region defining a central ink via, which is then etched to form the central ink via.

### BACKGROUND

1. Field of the Invention

The present invention relates to a printhead, and more particularly, to a method for forming an ink jetting device.

2. Description of the Related Art

A typical ink jet printhead includes a silicon chip to which a nozzle plate fabricated from a polymer material is attached. However, during printhead assembly, significant out-gassing and then al contraction may occur. Also, under certain conditions the polymer nozzle plate may tend to sag, thus affecting the accuracy and repeatability of ink drop placement. Other issues with current polymer nozzle plates, for example, are difficulty with adhesion of polymer to a substrate and print quality issues associated with alignment of nozzle holes after polymer cure. This disclosure references patent application Ser. No. 12/046,494 having a filing date of Mar. 12, 2008, which details the processing of the fluid-chamber using micro-electro-mechanical system (MS) techniques. Since the filing of patent application Ser. No. 12/046,494, further learning in the field of sacrificial polymers has opened up a new material set and new processing scheme to manufacture an inorganic fluid chamber that needs to be captured and protected.

Given the foregoing, it would be desirable therefore to provide a method for forming an ink jetting device by using a sacrificial polymer layer and a conformal nozzle layer and removing at least a portion of the sacrificial polymer layer by thermal decomposition for forming a fluid ejection device.

### SUMMARY OF THE INVENTION

Disclosed herein is a method for forming a fluid ejection device that includes providing a plurality of electrical heater elements on a first surface of a substrate, applying a polymer over at least a portion of the first surface to form a sacrificial polymer layer, applying a conformal material over at least a portion of the sacrificial polymer layer to form a conformal nozzle layer, removing at least a portion of the applied sacrificial polymer layer that cover the electrical heater elements by thermal decomposition to form a plurality of ejection chambers adjacent each of the plurality of electrical heater elements, removing at least a portion of the conformal nozzle layer to form a plurality of nozzle holes, each of the plurality of nozzle holes being disposed over a respective one of the plurality of electrical heater elements, applying a mask layer over a second surface of the substrate to provide an exposed region and an unexposed region, the exposed region defining a location of a central ink via, and etching the exposed region of the second surface of the substrate to form the central ink via in the substrate.

In some embodiments, the polymer material used in forming the sacrificial polymer layer has a temperature able to withstand temperatures necessary for deposition of a conformal nozzle layer.

In another embodiment, the pluralities of portions of the sacrificial polymer layer area define a symmetrical central channel with respect to a centerline.

In yet another aspect of the invention, disclosed is a method for forming a fluid ejection device on a substrate, the substrate having a first surface, a polymer is applied over at least a portion of the first surface to form a sacrificial polymer layer, applying a conformal material over at least a portion of the sacrificial polymer layer to form a conformal nozzle layer, forming a plurality of nozzle holes by removing at least a portion of the conformal nozzle layer, each of the plurality of nozzle holes being disposed over a respective one of the plurality of electrical heater elements, applying a mask layer over the second surface of the substrate to provide an exposed and an unexposed region, the exposed region defining a location of a central ink via, etching the exposed region of the second surface of the substrate to form a central ink via in the substrate and removing at least a portion of the applied sacrificial polymer layer that cover the electrical heater elements by thermal decomposition to form a plurality of ejection chambers.

In yet another aspect of the invention, a method for forming a thermal fluid ejection device is disclosed that includes providing a plurality of electrical heater elements on a first surface of a substrate, the substrate having a second surface located opposite the first surface, applying a thermally decomposable sacrificial polymer layer over at least a portion of the first surface, applying a conformal material over at least a portion of the sacrificial polymer layer to form a conformal nozzle layer, removing at least a portion of the conformal material to form a nozzle hole over each of the plurality of electrical heater elements, removing at least a portion of the applied thermally decomposable sacrificial polymer by thermal decomposition to form a plurality of ejection chambers, applying a mask layer over the second surface of the substrate to provide an exposed region and an unexposed region, the exposed region defining a via, and etching the via into the substrate.

### BRIEF DESCRIPTION OF THE DRAWINGS

The above-mentioned and other features and advantages of the various embodiments of the invention, and the manner of attaining them, will become more apparent and will be better understood by reference to the accompanying drawings, wherein:

FIG. 1A is a diagrammatic illustration of a top view of a substrate having heating elements provided thereon;

FIG. 1B is a cross section of the diagrammatic illustration of FIG. 1A taken along line 1B-1B;

FIG. 2A is a diagrammatic illustration of a top view of the substrate of FIGS. 1A, 1B with a sacrificial polymer layer deposited on at least a portion of the substrate;

FIG. 2B is a cross section of the diagrammatic illustration of FIG. 2A taken along line 2B-2B;

FIG. 3A is a diagrammatic illustration of a top view of the substrate and sacrificial polymer layer at the process stage of FIGS. 2A, 2B and after a conformal nozzle layer is deposited;

FIG. 3B is a cross section of the diagrammatic illustration of FIG. 3A taken along line 3B-3B;

FIG. 4A is a diagrammatic illustration of a top view of the substrate, sacrificial polymer layer, and conformal nozzle layer at the process stage of FIGS. 3A, 3B and after the removal of the sacrificial polymer layer to form the ink ejection chambers,

FIG. 4B is a cross section of the diagrammatic illustration of FIG. 4A taken along line 4B-4B;

FIG. 5A is a diagrammatic illustration of a top view of the substrate, sacrificial polymer layer, and conformal nozzle layer at the process stage of FIGS. 4A, 4B, and after formation of nozzle holes;

FIG. 5B is a cross section of the diagrammatic illustration of FIG. 5A taken along line 5B-5B;

FIG. 6A is a diagrammatic illustration of a top view of the substrate, sacrificial polymer layer, and conformal nozzle layer at the process stage of FIGS. 5A, 5B and after formation of a central ink via on the second portion of the substrate;

FIG. 6B is a cross section of the diagrammatic illustration of FIG. 6A taken along line 6B-6B;

FIG. 7A is a diagrammatic illustration of a top view of the substrate, sacrificial polymer layer, and conformal nozzle layer, after formation of a central ink via on the second portion of the substrate at the process stage of FIGS. 6A, 6B and removal of unexposed mask portion regions of the second portion of the substrate;

FIG. 7B is a cross section of the diagrammatic illustration of FIG. 7A taken along line 7B-7B;

FIG. 8 is a flowchart of a method for forming a fluid ejection device in accordance with an aspect of the present invention.

### DETAILED DESCRIPTION

Reference will now be made in detail to the exemplary embodiment(s) of the invention, as illustrated in the accompanying drawings. Whenever possible, the same reference numerals will be used throughout the drawings to refer to the same or like parts.

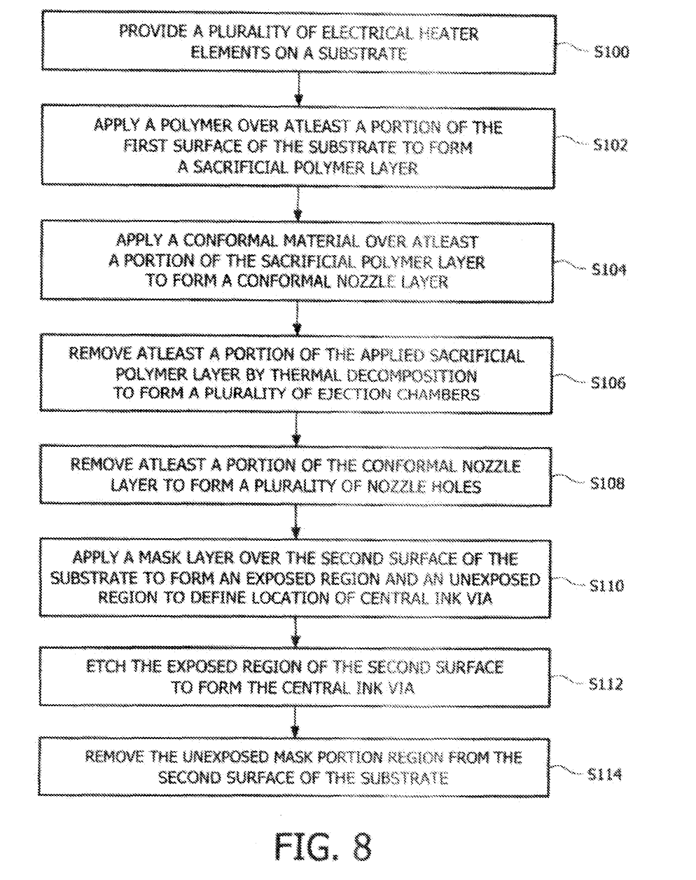

The various steps associated with the method for forming an ink jetting device in accordance with the present invention are summarized in the flow chart of FIG. 8.

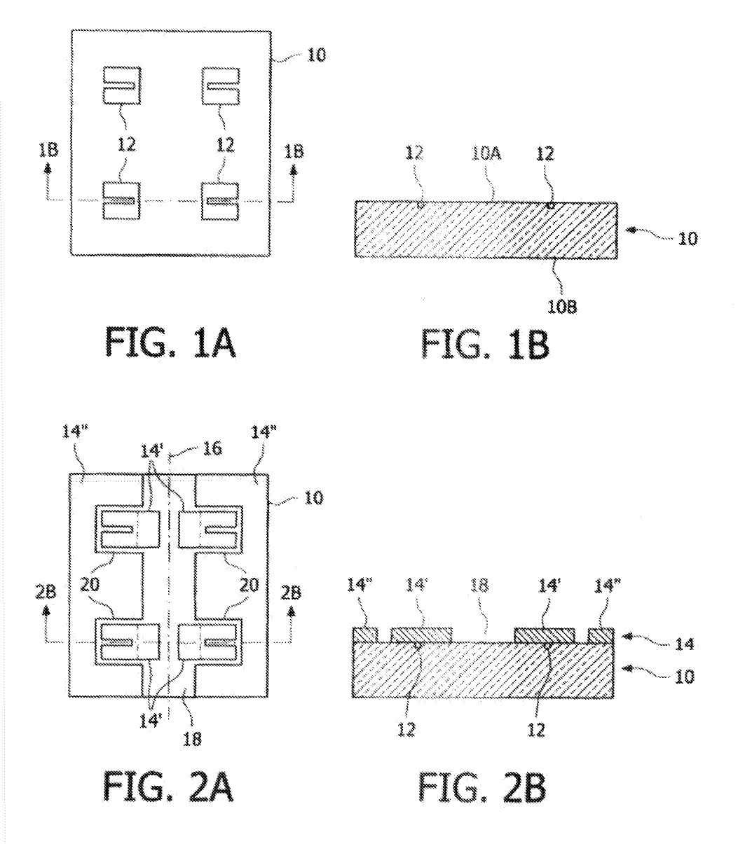

FIGS. 1A and 1B illustrate step S100 of flow chart of FIG. 8 that discloses a substrate 10 where a plurality of electrical heater elements 12 such as resistors are placed. The substrate 10 includes a first surface 10A and a second surface 10B. The second surface 10B which may be planar, is parallel to and on an opposite side of the first surface 10A of the substrate 10. The substrate 10 is pre-cleaned and has a plurality of electrical heater elements 12 provided on the first surface 10A of the substrate 10. The substrate 10 may be of any material, preferably one of a silicon or alumina. In the present embodiment, only four electrical heater elements 12 are shown, but it is to be understood that the actual number of electrical heater elements 12 may be in hundreds or thousands.

FIGS. 2A and 2B illustrates step S102 of flow chart of FIG. 8, where a polymer is applied over at least a portion of the first surface 10A to form a sacrificial polymer layer 14 that includes a first portion 14′ covering the electrical heater elements 12 and a second portion 14″ covering the edges of the substrate. The application of sacrificial polymer layer may be achieved, for example, by a spin-coat process, although other processes may be used.

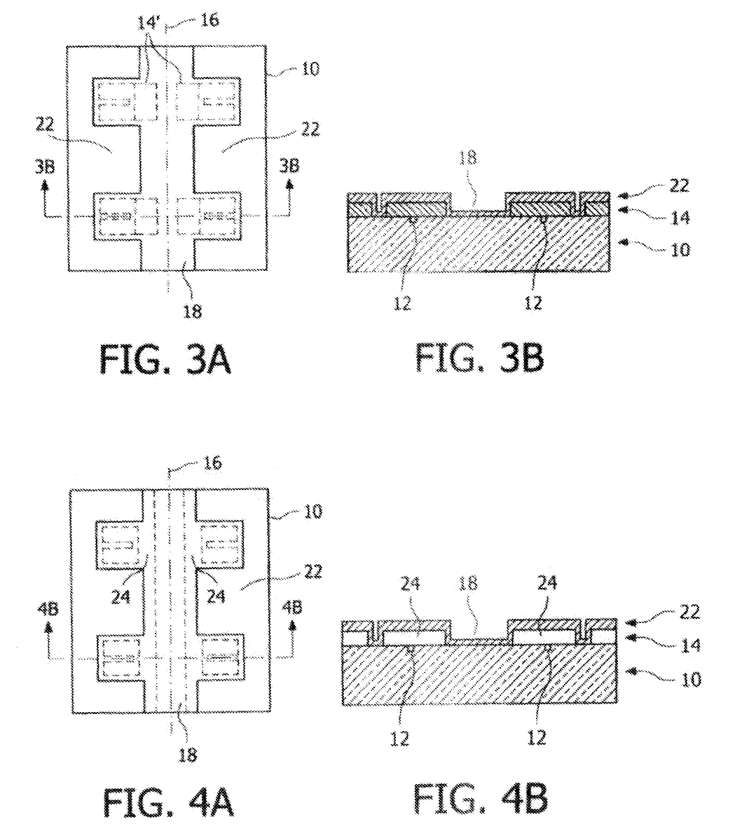

The composition of the sacrificial polymer material forming sacrificial polymer layers 14′ and 14″ may be a standard photoresist material and the desirable characteristics of the sacrificial polymer material include having a decomposition temperature higher than a deposition temperature of a conformal nozzle layer (FIG. 3) and capable of being patterned without the forming of a re-entrant profile in the sacrificial polymer layer. One example of such polymer material suitable for use as the sacrificial polymer material is polyimide, other polymer materials that also may be used include acrylonitrile butadiene styrene, polymethylmethacrylate, acrylonitrile, polytetrafluoroethylene, polyvinylidene fluoride, polyethylene terephthalate, polynorbornene, polycarbonate, etc.

Further, as shown in FIGS. 2A and 2B, the first portion 14′ of the sacrificial polymer layer 14 covers the electrical heater elements 12 and extends beyond the electrical heater elements 12 toward a centerline 16, such that the polymer layer covering the first portion 14′ and the second portion 14″ define a central channel 18 formed symmetrical with respect to centerline 16, which extends down to first surface 10A of substrate 10, and trenches 20 are formed that respectively extend from central channel 18 around the respective first portion 14′ of the sacrificial polymer layer 14. Central channel 18 and trenches 20 will aid in forming ink paths used for channeling ink flow to respective ink ejection chambers when at least a portion of the sacrificial polymer layer 14 is removed.

FIGS. 3A and 3B illustrate step S104 of flow chart of FIG. 8 where a conformal material is applied over at least a portion of the sacrificial polymer layer l4 to form a conformal nozzle layer 22. The application of the conformal nozzle layer 22 covers the first portion 14′ and second portion 14″ of the sacrificial polymer layer 14, central channel 18 and trenches 20.

The composition of the conformal nozzle layer 22 used in forming conformal nozzle layer 22 is selected such that the material is capable of completely filling trenches 20 formed in sacrificial polymer layer 14, since trenches 20 outline the walls for the ink ejection chambers 24 (FIG. 4). The material used in forming conformal nozzle layer 22 for the present embodiment may be a ceramic or a metallic thin film material such as one of a silicon oxide, silicon nitride, silicon oxynitride, polysilicon, tantalum and gold.

FIGS. 4A and 4B illustrate step S106 of flow chart of FIG. 8 where the first portion 14′ covering the electrical heater elements 12 (FIG. 2) is removed to form a plurality of ink ejection chambers 24. The ink ejection chambers 24 are formed respectively adjacent to electrical heater elements 12. The removal of the first portion 14′ of sacrificial polymer layer 14 may be achieved by a thermal decomposition process that rises to just below polymer thermal decomposition temperature and then rises slowly and holds at the thermal decomposition temperature.

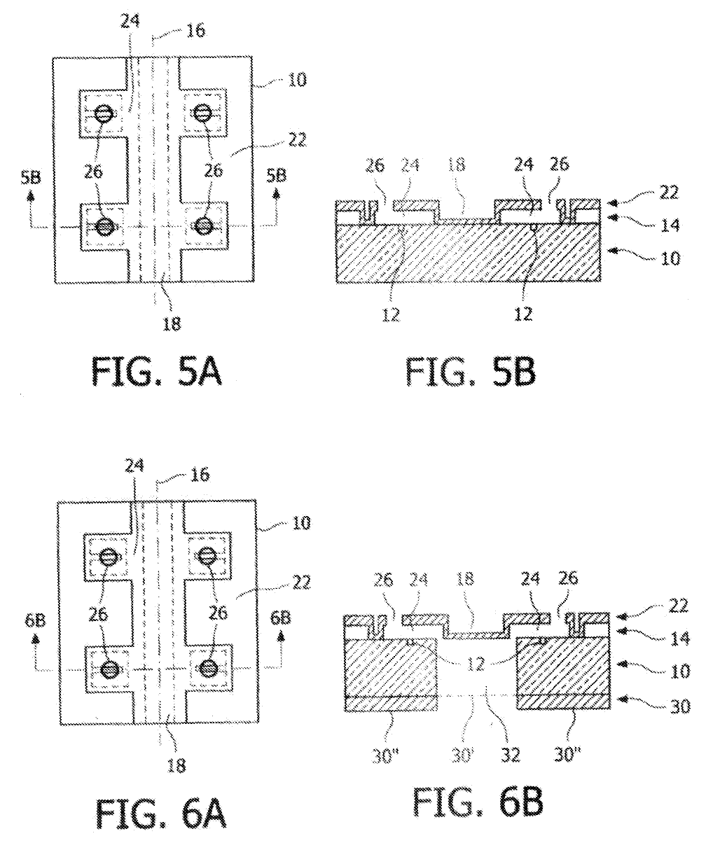

FIGS. 5A and 5B illustrate step S108 of flow chart of FIG. 8 where at least a portion of the conformal nozzle layer 22 is removed to form a plurality of nozzle holes 26, which extend down through conformal nozzle layer 22 to sacrificial polymer layer 14, and which are respectively located over electrical heater elements 12.

The formation of nozzle holes 26 in conformal nozzle layer 22 may be achieved by using, for example a standard photolithography and etch processes.

FIGS. 6A and 6B illustrate step S110 of the method where a mask layer 30 is applied over the second surface 10B of the substrate 10 to form an exposed region 30′ that separates two unexposed region mask portions 30″, which are located symmetrically with respect to centerline 16 (FIG. 2). At step S112 the exposed region 30′ of second surface 10B of the substrate 10 between the two separated unexposed region mask portions 30″ is etched to form a central ink via 32 in the substrate 10. The exposed region 30′ between the unexposed region mask portions 30″ define the location of the central ink via 32 which serves as a primary ink flow channel. The etching may be performed, for example, by a deep reactive ion etching (DRIE) process, a wet chemical etch, a mechanical blasting technique or some combination thereof.

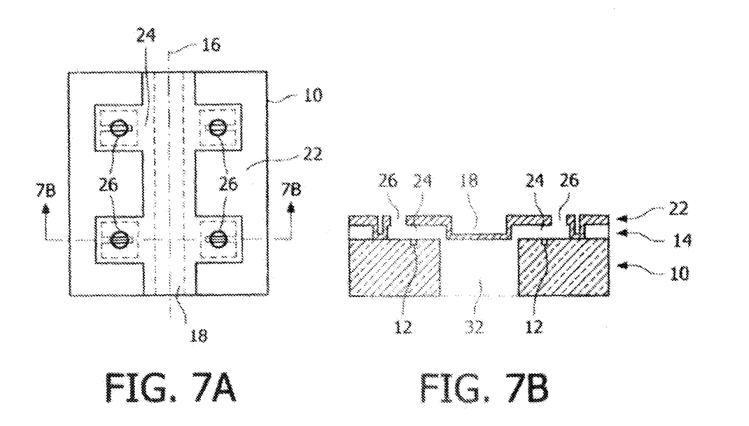

At step S114, the two unexposed region ink via mask portions 30″ are removed from the second surface 10B of the substrate 10 as shown in FIGS. 7A and 7B.

By using the process described above for forming a fluid ejection device, it is recognized that removal of first portion 14′ of the sacrificial polymer layer by thermal decomposition to form ink ejection chambers 24 allows flexibility in the process such that the opening of nozzle holes 26 can be done after removal of first portion 14′ as explained above. Thus, it is noted that the sequence of processing after the deposition of the conformal nozzle layer can be changed.

By forming the conformal nozzle layer 22 from a ceramic or metallic thin film material, the conformal nozzle layer 22 exhibits superior rigidity over that of a polymer nozzle plate i.e. it is less likely to sag, as is commonly observed in ink jetting devices that use a polymer printhead material over the ink vias. Also, a ceramic or metallic nozzle material is more stable than a polymer film over a range of temperatures.

It will be apparent to those skilled in the art that various modifications and variations can be made to the present invention without departing from the spirit and scope of the invention. Thus it is intended that the present invention cover the modifications and variations of this invention provided they come within the scope of the appended claims and their equivalents.

What is claimed is:

1. A method for forming a fluid ejection device on a substrate, the substrate having a first surface and a second surface, the second surface located opposite the first surface, and a plurality of electrical heater elements disposed on the first surface, comprising:
applying a polymer over at least a portion of the first surface to form a sacrificial polymer layer;
applying a conformal material over at least a portion of the sacrificial polymer layer to form a conformal nozzle layer;
removing at least a portion of the applied sacrificial polymer layer that cover the electrical heater elements by thermal decomposition to form a plurality of ejection chambers adjacent each of the plurality of electrical heater elements;
removing at least a portion of the conformal nozzle layer to form a plurality of nozzle holes, each of the plurality of nozzle holes being disposed over a respective one of the plurality of electrical heater elements;
applying a mask layer over the second surface of the substrate to provide an exposed region and an unexposed region, the exposed region defining a location of a central ink via; and
etching the exposed region of the second surface of the substrate to form the central ink via in the substrate.

2. The method of claim 1, wherein the polymer used in forming the sacrificial polymer has a decomposition temperature higher than a deposition temperature of the conformal nozzle layer.

3. The method of claim 1, wherein the substrate comprises a metal.

4. The method of claim 1, wherein said substrate is one of a silicon or alumina.

5. The method of claim 1, wherein the conformal material is one of a ceramic and a metallic thin film material.

6. The method of claim 1, wherein the conformal material is one of a silicon oxide, silicon nitride, silicon oxynitride, polysilicon, tantalum, and gold.

7. The method of claim 1, wherein the plurality of nozzle holes are formed in the conformal nozzle layer by photolithography and etching process.

8. The method of claim 1, wherein at least a plurality of portions of the sacrificial polymer layer area define a symmetrical central channel with respect to a centerline.

9. The method of claim 8, wherein at least a portion of the applied sacrificial polymer layer covers and extends beyond the electrical heater elements toward the centerline.

10. A method for forming a fluid ejection device on a substrate, the substrate having a first surface and a second surface opposite to the first surface, the first surface having a plurality of electrical heater elements, the method comprising:
applying a polymer over at least a portion of the first surface to form a sacrificial polymer layer;
applying a conformal material over at least a portion of the sacrificial polymer layer to form a conformal nozzle layer;
forming a plurality of nozzle holes by removing at least a portion of the conformal nozzle layer, each of the plurality of nozzle holes being disposed over a respective one of the plurality of electrical heater elements;
applying a mask layer over the second surface of the substrate to provide an exposed region and an unexposed region, the exposed region defining a location of a central ink via;
etching the exposed region of the second surface of the substrate to form a central ink via in the substrate; and
removing at least a portion of the applied sacrificial polymer layer that cover the electrical heater elements by thermal decomposition to form a plurality of ejection chambers.

11. The method of claim 10, wherein the polymer used in forming the sacrificial polymer layer has a decomposition-temperature higher than a deposition temperature of the conformal nozzle layer.

12. The method of claim 10, wherein the polymer used in forming the sacrificial polymer layer has characteristics selected to allow patterning without forming a re-entrant profile in the sacrificial polymer layer.

13. The method of claim 10, wherein at least a plurality of portions of the sacrificial polymer layer area define a symmetrical central channel with respect to a centerline, and wherein at least a portion of the applied sacrificial polymer layer covers and extends beyond the electrical heater elements toward the centerline.

14. The method of claim 10, wherein the substrate is made of a metal.

15. The method of claim 10, wherein the conformal material is one of a ceramic and a metallic thin film material.

16. The method of claim 10, wherein the conformal material is one of a silicon oxide, silicon nitride, silicon oxynitride, polysilicon, tantalum, and gold.

17. The method of claim 10, wherein the plurality of nozzle holes is formed in the conformal nozzle layer by photolithography and etching process.

18. The method of claim 10, wherein the exposed region of the second surface of the substrate is etched by a deep reactive ion etching process to form the central ink via in the substrate.

19. The method of claim 10, wherein the plurality of ejection chambers are formed respectively adjacent to the plurality of electrical heater elements.

20. A method for forming a thermal fluid ejection device on a substrate, the substrate having a first surface and a second surface, the second surface located opposite the first surface, and a plurality of electrical heater elements disposed on the first surface, comprising:
providing a plurality of electrical heater elements on a first surface of a substrate, the substrate having a second surface located opposite the first surface;
applying a thermally decomposable sacrificial polymer layer over at least a portion of the first surface;
applying a conformal material over at least a portion of the sacrificial polymer layer to form a conformal nozzle layer;
removing at least a portion of the conformal material to form a nozzle hole over each of the plurality of electrical heater elements;
removing at least a portion of the applied thermally decomposable sacrificial polymer by thermal decomposition to form a plurality of ejection chambers;
applying a mask layer over the second surface of the substrate to provide an exposed region and an unexposed region, the exposed region defining a via; and
etching the via into the substrate.
